(19) United States
(12) Patent Application Publication
(10) Pub. No.: US 2018/0138454 A1
(43) Pub. Date: May 17, 2018

(54) GLASS SUBSTRATES COMPRISING RANDOM VOIDS AND DISPLAY DEVICES COMPRISING THE SAME

(71) Applicant: CORNING INCORPORATED, CORNING, NY (US)

(72) Inventors: Minghan Chen, Saint Johns, FL (US); Ming-Jun Li, Horseheads, NY (US)

(21) Appl. No.: 15/553,349

(22) PCT Filed: Feb. 24, 2016
(86) PCT No.: PCT/US2016/019260

§ 371 Date: Aug. 24, 2017

Related U.S. Application Data
(60) Provisional application No. 62/121,715, filed on Feb. 27, 2015.

(51) Int. Cl. H01L 51/52; C03C 11/00; C03B 19/14; C03B 23/11; H01L 51/00

(52) U.S. Cl. CPC H01L 51/5268; C03C 11/00; H01L 51/0096; C03B 23/11; C03B 19/1453

(57) ABSTRACT

Disclosed herein are organic light-emitting diodes (OLEDs) comprising an anode, a hole transporting layer, an emitting layer, an electron transporting layer, a cathode, and at least one glass substrate, wherein the at least one glass substrate comprises a first surface, an opposing second surface, and a plurality of voids disposed therebetween, wherein the void fill fraction of the glass substrate is at least about 0.1% by volume. Display devices comprises such OLEDs are also disclosed herein. Methods for making glass substrates are further disclosed herein.

### CROSS-REFERENCE TO RELATED APPLICATIONS

This application claims the benefit of priority under 35 U.S.C. § 119 of U.S. Provisional Application Ser. No. 62/121,715 filed on Feb. 27, 2015, the content of which is relied upon and incorporated herein by reference in its entirety.

### FIELD OF THE DISCLOSURE

The disclosure relates generally to glass substrates and display devices comprising such substrates, and more particularly to light extraction layers comprising random air lines and OLED display devices comprising the same.

### BACKGROUND

High-performance display devices, such as liquid crystal (LC), organic light-emitting diode (OLED), and plasma displays, are commonly used in various electronics, such as cell phones, laptops, electronic tablets, televisions, and computer monitors. Currently marketed display devices can employ one or more high-precision glass sheets, for example, as substrates for electronic circuit components, as light extraction layers, as light guide plates, or as color filters, to name a few applications. OLED light sources have increased in popularity for use in display and lighting devices due to their improved color gamut, high contrast ratio, wide viewing angle, fast response time, low operating voltage, and/or improved energy efficiency. Demand for OLED light sources for use in curved displays has also increased due to their relative flexibility.

A basic OLED structure can comprise an organic light-emitting material disposed between an anode and a cathode. The multi-layer structure can include, for example, an anode, a hole injection layer, a hole transporting layer, an emitting layer, an electron transporting layer, an electron injection layer, and a cathode. During operation, the injected electrons from the cathode and holes from the anode can be recombined in the emitting layer to generate excitons. When current is supplied to the organic light emitting material, light is given off due to the radioactive decay of the excitons. To form a display device comprising an OLED, a plurality of anodes and cathodes can be driven by a thin film transistor (TFT) circuit. The TFT array thus provides an array of pixels which can then be used to display selected images by the application of current through the anodes and cathodes.

While OLED display devices may have numerous advantages over other display devices, such as LCDs, OLEDs may still suffer from one or more drawbacks. For example, OLEDs can have limited light output efficiency (luminance) as compared to other light sources. In some instances, as much as 80% of the light energy emitted by the OLED may be trapped in the display device. Light generated by the emitting layer can, for instance, be confined within the electrode and glass substrate of the device due to a large difference in refractive index (n) values for these layers (e.g., nₑ≈1.9, n_{g}≈1.5). Snell's law suggests that the difference in refractive indices produces a low out-coupling efficiency in the range of about 20%, where the efficiency level is expressed as the ratio of surface emission to the total emitted light. Thus, even though internal efficiencies nearing 100% have been reported, the low out-coupling efficiency ultimately limits the brightness and efficiency of the OLED device.

Numerous methods for improving light extraction efficiency of OLED devices have been proposed, including substrate surface modification, diffraction grating, and low index grids. However, these techniques all require expensive and complex processes, such as photolithography and the like, which can unnecessarily increase the manufacturing time and overall cost of the device. Attempts to increase the light output of an OLED device have also included driving the OLED at relatively high current levels. However, such high currents can have a negative impact on the lifespan of the OLED and thus also fail to provide an ideal solution.

Accordingly, it would be advantageous to provide methods and substrates for OLED devices that can provide improved light extraction efficiency and/or increased lifespan while also reducing the cost, complexity, and/or time for manufacturing the OLED device. In various embodiments, display devices (such as OLED displays) comprising such substrates may have one or more advantages, such as improved brightness, color gamut, contrast ratio, viewing angle, response time, flexibility, and/or energy efficiency.

### SUMMARY

The disclosure relates, in various embodiments, to organic light-emitting diodes (OLEDs) comprising an anode, a hole transporting layer, an emitting layer, an electron transporting layer, a cathode, and at least one glass substrate, wherein the at least one glass substrate comprises a first surface, a second surface, and a plurality of voids disposed therebetween, wherein the void fill fraction of the glass substrate is at least about 0.1% by volume. Glass sheets comprising a first surface, an opposing second surface, and a plurality of voids disposed therebetween are also disclosed herein. Display devices comprising such glass substrates and OLEDs are also disclosed herein.

According to various embodiments, the voids can have a round or elongated shape. In some embodiments, each of the plurality of voids can comprise a diameter ranging from about 0.01 μm to about 100 μm, and an average diameter of the plurality of voids can range from about 0.1 μm to about 10 μm. In other embodiments, each of the plurality of voids can have a length ranging from about 0.01 μm to about 2000 μm, and an average length of the plurality of voids can range from about 0.1 μm to about 200 μm. The average fill fraction of the plurality of voids can range, for example, from about 0.1 to about 10%. According to certain embodiments, the glass substrate can have a haze of at least 40% and/or a thickness ranging from about 0.1 mm to about 3 mm. In additional embodiments, the plurality of voids can have a longitudinal axis extending in a direction substantially perpendicular to the first and/or second surfaces.

Further disclosed herein are methods for making a glass substrate, the methods comprising depositing glass precursor particles by vapor deposition to form a substrate, and consolidating the substrate in the presence of at least one gas to form a glass substrate comprising a plurality of voids. In additional embodiments, the glass substrate may be drawn to form an elongated glass substrate comprising a plurality of elongated voids. A glass sheet or other structure can be cut or otherwise formed from the elongated glass substrate according to various embodiments. The glass precursor particles can comprise, for example, silica optionally doped with at least one component chosen from germania, alumina, titania, or zirconia, and combinations thereof. Vapor deposition can be carried out using vapors selected from SiCl₄, GeCl₄, AlCl₃, TiCl₄, ZrCl₄, and combinations thereof, to name a few. Consolidation of the substrate to form a glass substrate comprising a plurality of voids can comprise, in various embodiments, heating the substrate to a temperature ranging from about 1100° C. to about 1500° C. in the presence of at least one gas chosen from air, O₂, N₂, SO₂, Kr, Ar, and combinations thereof.

Additional features and advantages of the disclosure will be set forth in the detailed description which follows, and in part will be readily apparent to those skilled in the art from that description or recognized by practicing the methods as described herein, including the detailed description which follows, the claims, as well as the appended drawings.

It is to be understood that both the foregoing general description and the following detailed description present various embodiments of the disclosure, and are intended to provide an overview or framework for understanding the nature and character of the claims. The accompanying drawings are included to provide a further understanding of the disclosure, and are incorporated into and constitute a part of this specification. The drawings illustrate various embodiments of the disclosure and together with the description serve to explain the principles and operations of the disclosure.

### BRIEF DESCRIPTION OF THE DRAWINGS

The following detailed description can be further understood when read in conjunction with the following drawings.

FIG. 1 illustrates a light emitting device according to various embodiments of the disclosure;

FIG. 2 depicts an exemplary glass substrate according to certain embodiments of the disclosure;

FIG. 3 depicts a cross-sectional view of a glass substrate comprising a plurality of voids according to various embodiments of the disclosure;

FIG. 4 depicts a cross-sectional view of a glass substrate comprising a plurality of voids according to certain embodiments of the disclosure;

FIG. 5 depicts emitted light from an OLED comprising regular glass and glass comprising a plurality of voids according to various embodiments of the disclosure; and

FIG. 6 is a graphical depiction of the intensity profile of an OLED employing a regular glass substrate and a glass substrate comprising a plurality of voids.

### DETAILED DESCRIPTION

Devices

Disclosed herein are OLEDs comprising an anode, a hole transporting layer, an emitting layer, an electron transporting layer, a cathode, and a glass substrate, wherein the glass substrate comprises a first surface, a second surface, and a plurality of voids disposed therebetween, wherein the fill fraction of voids is at least about 0.1% by volume. Glass sheets comprising a first surface, an opposing second surface, and a plurality of voids disposed therebetween are also disclosed herein, wherein the fill fraction of voids is at least about 0.1% by volume. Display devices comprising such OLEDs and glass substrates are also disclosed herein.

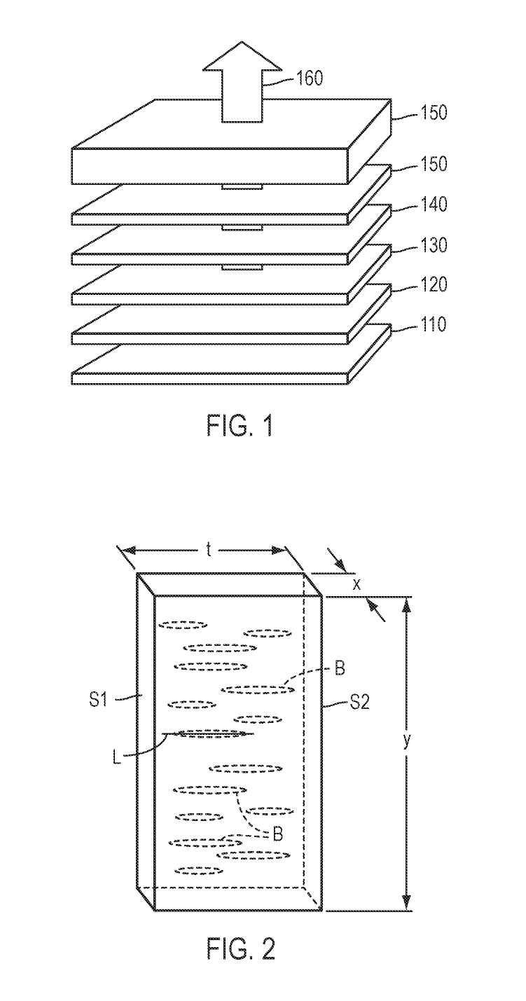

FIG. 1 depicts an exemplary light emitting device according to various embodiments of the disclosure. The device can comprise a cathode 110, an electron transporting layer 120, an emissive layer 130, a hole transporting layer 140, an anode 150, and a glass substrate 160. In the depicted embodiment, the device may emit light through the glass substrate 160, in which case the anode 150 may comprise a substantially transparent or semi-transparent material, such as indium tin oxide (ITO) or any other conductive material with a suitable transparency. In other embodiments, the device can emit light through a transparent or semi-transparent cathode 110, e.g., an organic layer, in which case the glass substrate 160 may be positioned adjacent the cathode 110 (not depicted). Additional layers in the light emitting device can include a hole injection layer (HIL) and/or an electron injection layer (EIL) (not illustrated). Glass substrates disclosed herein can be utilized in the OLED device as substrate 160, e.g., as a light scattering layer and a glass substrate, or can be used in addition to substrate 160, e.g., as a supplemental light scattering layer.

The glass substrate can comprise a first surface and an opposing second surface. In some embodiments, the glass substrate can be a glass sheet. The surfaces may, in certain embodiments, be planar or substantially planar, e.g., substantially flat and/or level. The glass substrate can also, in some embodiments, be curved about at least one radius of curvature, e.g., a three-dimensional glass substrate, such as a convex or concave substrate. The first and second surfaces may, in various embodiments, be parallel or substantially parallel. The glass substrate may further comprise at least one edge, for instance, at least two edges, at least three edges, or at least four edges. By way of a non-limiting example, the glass substrate may comprise a rectangular or square glass sheet having four edges, although other shapes and configurations are envisioned and are intended to fall within the scope of the disclosure. According to various embodiments, the glass substrate may have a refractive index ranging from about 1.3 to about 1.7, such as from about 1.4 to about 1.6, or about 1.5, including all ranges and subranges therebetween.

As shown in FIG. 2, an exemplary glass substrate can have a length y extending in a first direction, a width x extending in a second direction, and a thickness t extending in a third direction. Of course, while the substrate as shown is rectangular, it is to be understood that the depicted size, shape, and/or orientation is not limiting and other shapes, such as squares, other sizes, such as varying lengths, widths, and/or thicknesses, and other orientations are possible. Furthermore, while certain sides are labeled as length or width, it is to be understood that these labels can be reversed without limitation. The glass substrate as disclosed herein can comprise a plurality of voids B disposed between the first and second surfaces S1 and S2.

The plurality of voids B can comprise round or elongated voids, or a mixture of both. In certain embodiments, the voids may be envisioned as bubbles, channels, tubes, or air lines extending through the glass substrate. As used herein, the term “elongated” and variations thereof is intended to denote that the voids are not round or spherical, e.g., that the voids have a length that is larger than a width of the voids. The elongated voids can have, for example, a longitudinal axis L extending along the largest dimension of the void. In certain embodiments, the plurality of voids can be oriented in the glass substrate such that the longitudinal axis of the voids extends in a direction substantially perpendicular to the first and/or second surfaces S1 and S2 of the glass substrate. In some embodiments, the longitudinal axis L of the voids can be substantially transverse, e.g., perpendicular to plane x-y and substantially parallel to plane x-t. According to further embodiments, the length y of the substrate can extend in a first direction and the width x can extend in a second direction, and the longitudinal axis L of the plurality of voids can extend in a direction substantially transverse, e.g., substantially perpendicular, to the first and/or second directions. In still further embodiments, the thickness t can extend in a third direction and the longitudinal axis L of the plurality of voids can extend in a direction substantially parallel to the third direction. According to yet further embodiments, the plurality of voids B can be oriented such that the longitudinal axis L of each void extends in substantially the same direction. By way of a non-limiting example, the plurality of voids can comprise round voids (not shown) having an average diameter that can be the same or can vary from void to void.

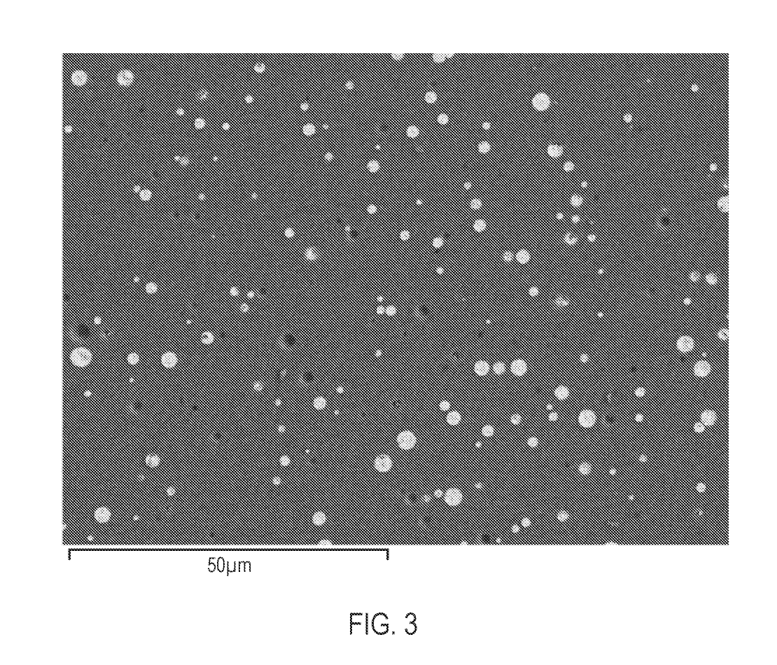

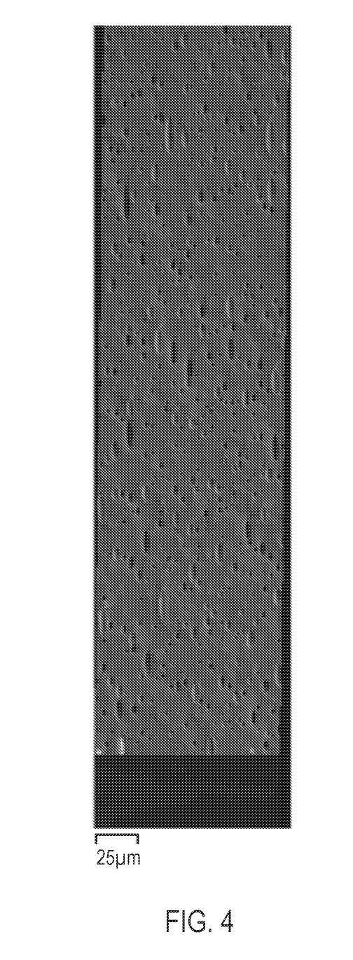

FIG. 3 is a scanning electron microscope (SEM) cross-sectional view of an exemplary glass substrate, e.g., a glass rod having a given diameter and a length, taken along the diameter of the rod. Similarly, FIG. 4 is an SEM fracture image of the glass rod, taken along the length of the rod. Referring to FIG. 3, each void in the plurality of voids can independently have a diameter ranging from about 0.01 μm to about 100 μm, such as from about 0.1 μm to about 90 μm, from about 0.5 μm to about 80 μm, from about 1 μm to about 70 μm, from about 2 μm to about 60 μm, from about 3 μm to about 50 μm, from about 4 μm to about 40 μm, from about 5 μm to about 30 μm, or from about 10 μm to about 20 μm, including all ranges and subranges therebetween. As shown in FIG. 3, each void in the plurality of voids need not have the same diameter. An overall average diameter for the plurality of voids can range, in some embodiments, from about 0.1 μm to about 10 μm, such as from about 0.5 μm to about 9 μm, from about 1 μm to about 8 μm, from about 2 μm to about 7 μm, from about 3 μm to about 6 μm, or from about 4 μm to about 5 μm, including all ranges and subranges therebetween.

Similarly, referring to FIG. 4, each void in the plurality of voids can independently have a length ranging from about 0.01 μm to about 2000 μm, such as from about 0.1 μm to about 1500 μm, from about 0.5 μm to about 1000 μm, from about 1 μm to about 500 μm, from about 2 μm to about 400 μm, from about 3 μm to about 300 μm, from about 4 μm to about 200 μm, from about 5 μm to about 100 μm, or from about 10 μm to about 50 μm, including all ranges and subranges therebetween. As shown in FIG. 4, each void in the plurality of voids need not have the same length. An overall average length for the plurality of voids can range, in some embodiments, from about 1 μm to about 200 μm, such as from about 5 μm to about 150 μm, from about 10 μm to about 100 μm, or from about 25 μm to about 50 μm, including all ranges and subranges therebetween. According to various embodiments, the voids can be elongated voids having a diameter (D) and a length (L). A ratio between the diameter and length D:L can range, for example, from about 1:5 to about 1:1000, such as from about 1:10 to about 1:900, from about 1:20 to about 1:800, from about 1:30 to about 1:700, from about 1:40 to about 1:600, from about 1:50 to about 1:500, from about 1:100 to about 1:400, or from about 1:200 to about 1:300, including all ranges and subranges therebetween.

Referring to FIGS. 3-4, it can additionally be seen that the plurality of voids may be distributed throughout the glass substrate in a random pattern, e.g., the position of each void in the plurality may vary in an irregular manner. As noted above, each void size may also vary randomly, thus yielding a plurality of variously shaped voids spaced apart at various intervals. Of course, it is also possible to employ a glass substrate having an arranged pattern of voids, e.g., voids having similar shapes and sizes and/or distributed throughout the glass substrate in an arranged fashion. It is also noted that both black and white dots and lines in each figure represent voids. It is also noted that not all voids in the glass substrate need be the same shape, e.g., elongated or round. Rather, the substrate can comprise a mixture of a plurality of spherical voids and a plurality of elongated voids. The size, shape, and number of voids can be controlled, for example, by varying the gas to which the substrate is exposed during the vapor deposition process, the consolidation time, and/or the consolidation temperature, as discussed in more detail below with respect to the disclosed methods.

As used herein, the terms “fill fraction,” “fill factor,” and variations thereof is intended to denote the ratio of the volume of voids to the total volume of the glass substrate. According to various embodiments, the glass substrate can comprise at least about 0.1% by volume of voids, such as at least about 0.2%, 0.3%, 0.4%, 0.5%, 0.6%, 0.7%, 0.8%, 0.9%, 1%, 2%, 3%, 4%, 5%, 6%, %, 8%, 9%, or 10% by volume of voids, including all ranges and subranges therebetween. In additional embodiments, the glass substrate can comprise at least about 10%, at least about 15%, at least about 20%, at least about 25%, at least about 30%, at least about 35%, at least about 40%, at least about 45%, or at least about 50% by volume of voids, including all ranges and subranges therebetween. The fill fraction (or fill factor) of the voids can range, in non-limiting embodiments, from about 0.1% to about 10%, such as from about 0.2% to about 9%, from about 0.3% to about 8%, from about 0.4% to about 7%, from about 0.5% to about 6%, from about 0.6% to about 5%, from about 0.7% to about 4%, from about 0.8% to about 3%, from about 0.9% to about 2%, or from about 1% to about 1.5%, including all ranges and subranges therebetween.

In additional embodiments, the glass substrates disclosed herein may have a haze of at least about 40%. As used herein, “haze” is referred to as the percentage of light which deviates from the incident beam at an angle greater than 2.5 degrees on average when passing through a substrate (ASTM D 1003). An exemplary glass substrate as disclosed herein may have greater than about 40% haze, such as greater than about 45%, 50%, 55%, 60%, 65%, 70%, 75%, 80%, 85%, 90%, 95%, 96%, 97%, 98%, or 99%, including all ranges and subranges therebetween.

The glass substrate may comprise any glass known in the art for use as a glass substrate in an OLED including, but not limited to, aluminosilicate, alkali-aluminosilicate, borosilicate, alkali-borosilicate, aluminoborosilicate, alkali-alum inoborosilicate, and other suitable glasses. In certain embodiments, the glass substrate may have a thickness of less than or equal to about 3 mm, for example, ranging from about 0.1 mm to about 2.5 mm, from about 0.3 mm to about 2 mm, from about 0.7 mm to about 1.5 mm, or from about 1 mm to about 1.2 mm, including all ranges and subranges therebetween. Non-limiting examples of commercially available glasses suitable for use as a light filter include, for instance, EAGLE XG®, Iris™, Lotus™, Willow®, and Gorilla® glasses from Corning Incorporated. Suitable glasses are disclosed, for example, in U.S. Pat. Nos. 8,586,492, 8,652,978, 7,365,038, 7,833,919, RE38959, and U.S. prov. Appl. Nos. 62/026,264, 62/014,382, and 62/114,825, all of which are incorporated herein by reference in their entireties.

Methods

Glass substrates disclosed herein can be made by depositing glass precursor particles by vapor deposition to form a substrate; and consolidating the substrate in the presence of at least one gas to form a glass substrate comprising a plurality of voids. In additional embodiments, the methods may further include drawing the glass substrate to form an elongated glass substrate comprising a plurality of elongated voids. According to various embodiments, a glass sheet or other shape can be formed from the glass substrate or elongated glass substrate, e.g., by cutting a desired shape from the substrate.

For example, a glass substrate or rod can be fabricating using an outside vapor deposition (OVD) laydown process. In this process, glass precursor particles, such as silica optionally doped with germania, alumina, titania, zirconia, or combinations thereof, can be deposited to form a substrate. Vapors for use in the OVD process can be chosen, for instance, from SiCl₄, GeCl₄, AlCl₃, TiCl₄, ZrCl₄, and combinations thereof, to name a few. The substrate thus formed may be referred to as a “soot blank,” such as a silica soot blank, where “soot” refers to the particles deposited during the process. The vapors can, in some embodiments, pass through a flame burner or other heating device, at which time they can react with at least one delivery gas to form soot particles. Suitable delivery gases can include, for example, CH₄, O₂, H₂, and combinations thereof. In various embodiments, the reaction temperature can range from about 1500° C. to about 2200° C., such as from about 1800° C. to about 2100° C., or from about 1850° C. to about 2000° C., including all ranges and subranges therebetween. In certain embodiments, a bait rod or other device can be used to attract the particles for deposition. The bait rod can, for example, rotate during the vapor deposition process and serve as a substrate onto which the soot particles can land and accumulate. According to various embodiments, the bait rod can be removed from the substrate prior to consolidation.

After the laydown process, the substrate or soot blank can be optionally dried prior to consolidation. For instance, drying can be carried out at a first temperature ranging from about 900° C. to about 1200° C., such as from about 950° C. to about 1150° C., from about 1000° C. to about 1125° C., or from about 1050° C. to about 1100° C., including all ranges and subranges therebetween. In some embodiments, the substrate can be placed in a furnace, such as a consolidation furnace, or any other suitable apparatus for heating the substrate. Drying may take place optionally in the presence of at least one gas, for example, air, Cl₂, N₂, O₂, SO₂, Ar, Kr, or combinations thereof. Drying times can vary as desired, depending, e.g., on the substrate properties, and can range, for example, from about 10 minutes to 2 hours, such as from about 20 minutes to about 1.5 hours, or from about 30 minutes to about 1 hour, including all ranges and subranges therebetween.

After an optional drying step, the substrate may be consolidated by heating the substrate to a second temperature ranging from about 1100° C. to about 1600° C., such as from about 1150° C. to about 1500° C., from about 1200° C. to about 1450° C., from about 1250° C. to about 1400° C., or from about 1300° C. to about 1350° C., including all ranges and subranges therebetween. Consolidation may be carried out in the presence of at least one gas chosen from N₂, O₂, SO₂, Ar, Kr, and combinations thereof, to name a few. Heat can be supplied by placing the substrate in a furnace, such as a consolidation furnace, or any other suitable apparatus. Consolidation times can vary depending on the application and/or the desired properties of the glass substrate and can range, for example, from about 1 hour to about 5 hours, such as from about 2.5 hours to about 4.5 hours, or from about 2 hours to about 3 hours, including all ranges and subranges therebetween.

The glass substrate can be drawn to form an elongated glass substrate using any suitable method known in the art. For instance, the glass substrate may be heated, e.g., to a temperature ranging from about 1800° C. to about 2100° C., such as from about 1900° C. to about 2050° C., or from about 1950° C. to about 2000° C., including all ranges and subranges therebetween, and subsequently stretched, elongated, or drawn out. In certain embodiments, the glass substrate can be drawn to a length that is at least about 10% greater than the original length, such as at least about 15%, 20%, 25%, 30%, 35%, 40%, 45%, 50%, 55%, 60%, 65%, 70%, 75%, 80%, 85%, 90%, 95%, 100%, or greater, including all ranges and subranges therebetween. Glass shapes, such as glass sheets, can be subsequently cut from the elongated glass substrate to a desired shape and size and can be optionally finished or otherwise processed using any known methods. According to one non-limiting embodiment, in the case of a glass rod, the glass rod may be cut along its diameter to form substantially circular glass discs, which may then be further cut or shaped to achieve the desired dimensions. In other embodiments, glass shapes, such as sheets, may be cut from the glass substrate without first elongating the substrate, e.g., such that the voids are rounder and/or less elongated.

After forming a substrate having the desired sheet, e.g., a glass sheet, various additional processing steps. For example, the substrate may be cleaned, polished, finished, and so forth. In some embodiments, the substrate may be treated to reduce or eliminate voids on the glass surfaces. For instance, the glass substrate may be locally reheated at the surface to melt a portion of the glass materials at the surface such that any void regions (or partial voids formed during the cutting process) collapse, to form a substantially smooth surface. In other embodiments, the one or both glass surface can be coated with at least one polymeric layer to fill any voids or partial voids such that the glass surface(s) are substantially smooth.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. Thus, for example, reference to “a void” includes examples having two or more such voids unless the context clearly indicates otherwise. Likewise, a “plurality” is intended to denote “more than one.” As such, a “plurality of voids” includes two or more such voids, such as three or more such voids, etc.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In some embodiments, “substantially similar” may denote values within about 10% of each other, such as within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a device that comprises A+B+C include embodiments where a device consists of A+B+C and embodiments where a device consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

The following Examples are intended to be non-restrictive and illustrative only, with the scope of the invention being defined by the claims.

### Examples

Silica particles were deposited to form a silica soot blank by an outside vapor deposition (OVD) laydown process. Vapors comprising SiCl₄ were reacted with delivery gases CH₄ and O₂ at a temperature of about 2000° C. The resulting silica particles were deposited to form a silica soot blank, which was then dried in the presence of Cl₂ gas at 1125° C. for 1 hour in a consolidation furnace. Consolidation was carried out in the presence of 100% N₂ gas at 1490° C. for 2 hours in the consolidation furnace. The N₂ gas became trapped in the blank during sintering to form a glass substrate with randomly distributed air voids. The glass substrate was then drawn into a glass rod having a substantially circular cross-section with a diameter of 1 inch. A disc-shaped glass sheet having a thickness of about 0.5 mm was cut from the glass rod (e.g., by making a cut transverse to the length of the rod).

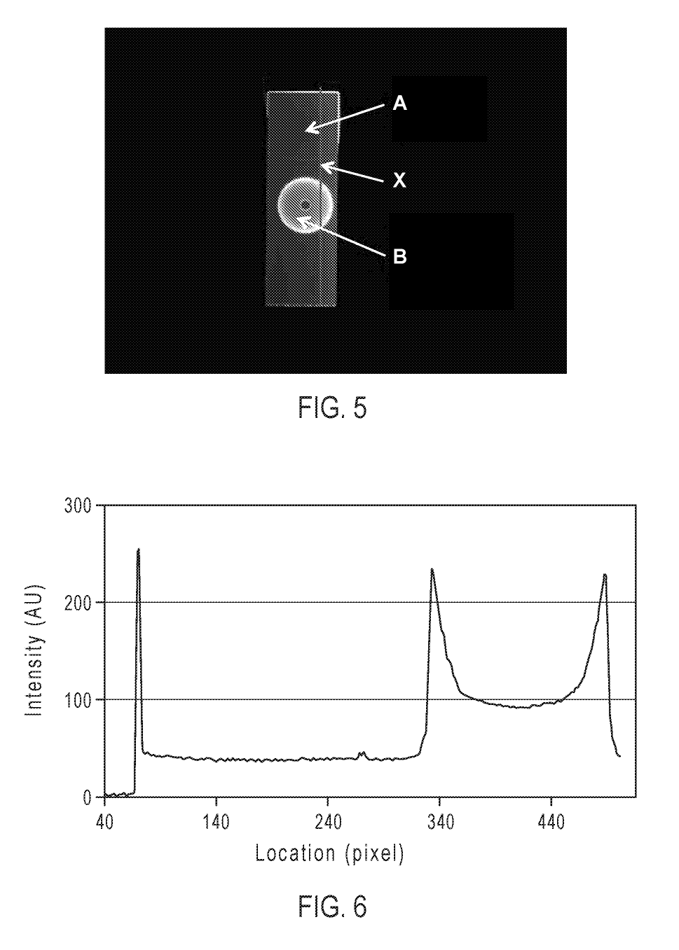

Light extraction efficiency of the glass sheet comprising a plurality of voids was compared to regular glass not comprising voids. A regular glass substrate and a glass substrate comprising voids were placed on top of OLED Alq₃ fluorescence materials, and index matching oil was placed on the glass surfaces in contact with the OLED materials. UV light was then employed to excite the fluorescence materials. In FIG. 5, region A corresponds to regular glass laid over the fluorescence materials and region B corresponds to glass comprising voids laid over the fluorescence materials. It can be seen that region B shows a much brighter intensity than region A. FIG. 6 further depicts a quantitative intensity profile measured along the line X shown in FIG. 5. An average light extraction efficiency of 2.5 for region B as compared to region A was calculated. The small center region in region B (which does not comprise voids) was not considered in the calculation.

The haze of the glass substrate comprising the voids was measured as 98%, which is believed to potentially account for at least a portion of the improved light extraction efficiency. Finally, a Zemax non-sequential ray tracing model was developed to simulate the light scattering process within the glass substrate to further investigate the physics of the light extraction efficiency of the glass substrate comprising a plurality of voids. A source layer was placed in contact with the glass layer (0.5 mm). A Mie scattering model was employed with 1.58 μm assumed particle size. The Zemax model calculated a theoretical light extraction efficiency of about 2.7, which is in agreement with the experimental results discussed above.

1. An organic light-emitting diode comprising:
(a) a cathode;
(b) an electron transporting layer;
(c) an emitting layer;
(d) a hole transporting layer;
(e) an anode; and
(f) at least one glass substrate comprising a first surface, a second opposing surface, and a plurality of voids disposed therebetween, wherein a void fill fraction of the at least one glass substrate is at least about 0.1% by volume.

2. The organic light-emitting diode of claim 1, wherein each of the plurality of voids comprises a diameter independently ranging from about 0.01 μm to about 100 μm.

3. The organic light-emitting diode of claim 1, wherein the average diameter of the plurality of voids ranges from about 0.1 μm to about 10 μm.

4. The organic light-emitting diode of claim 1, wherein the at least one glass sheet comprises a plurality of elongated voids.

5. The organic light-emitting diode of claim 4, wherein each of the elongated voids comprises a length independently ranging from about 0.01 μm to about 2000 μm.

6. The organic light-emitting diode of claim 4, wherein the average length of the elongated voids ranges from about 0.1 μm to about 200 μm.

7. The organic light-emitting diode of claim 1, wherein the fill fraction of the plurality of voids ranges from about 0.1 to about 10%.

8. The organic light-emitting diode of claim 1, wherein the at least one glass substrate has a haze value of at least about 40%.

9. The organic light-emitting diode of claim 1, wherein the at least one glass substrate comprises a plurality of elongated voids, and wherein a longitudinal axis of the plurality of elongated voids extends in a direction perpendicular to the first and second surfaces of the glass substrate.

10. The organic light-emitting diode of claim 1, wherein the at least one glass substrate has a thickness ranging from about 0.1 mm to about 3 mm.

11. A display device comprising the organic light-emitting diode of claim 1.

12. A method for making a glass substrate, comprising:
depositing glass precursor particles by vapor deposition to form a substrate; and
consolidating the substrate in the presence of at least one gas to form a glass substrate comprising a plurality of voids.

13. The method of claim 12, further comprising drawing the glass substrate to form an elongated glass substrate comprising a plurality of elongated voids; and optionally forming a glass sheet from the elongated glass substrate.

14. The method of claim 12, wherein the glass precursor particles comprise silica optionally doped with at least one component chosen from germania, alumina titania, or zirconia, and combinations thereof.

15. The method of claim 12, wherein the vapor is chosen from SiCl₄, GeCl₄, AlCl₃, TiCl₄, ZrCl₄, and combinations thereof.

16. The method of claim 12, wherein consolidating the substrate comprises heating the substrate to a first temperature ranging from about 1100° C. to about 1500° C., and wherein the at least one gas is chosen from air, O₂, N₂, SO₂, Kr, Ar, and combinations thereof.

17. The method of claim 12, further comprising drying the substrate at a temperature ranging from about 900° C. to about 1200° C. for about 10 minutes to about 1 hour, optionally in the presence of at least one additional gas chosen from air, Cl₂, O₂, N₂, SO₂, Kr, Ar, and combinations thereof.

18. The method of claim 12, wherein the glass substrate comprising the plurality of voids is a glass rod, and wherein the method further comprises cutting a glass sheet from the glass rod.

19. A glass sheet comprising a first surface, an opposing second surface, and a plurality of elongated voids disposed therebetween having a longitudinal axis substantially perpendicular to the first and second surfaces.

20. The glass sheet of claim 19, wherein the plurality of elongated voids have an average diameter ranging from about 0.1 μm to about 10 μm and an average length ranging from about 1 μm to about 200 μm.

21. The glass sheet of claim 19, wherein the glass sheet has a void fill fraction of at least about 0.1% by volume and/or a haze of at least about 40%.
